(19) United States
(12) Patent Application Publication
(10) Pub. No.: US 2003/0022458 A1
(43) Pub. Date: Jan. 30, 2003

(54) Method for forming a shallow trench isolation in a semiconductor structure

(76) Inventor: Chao-Ming Koh, Hsinchu (TW)

Correspondence Address: Clement Cheng, Esq., 17220 Newhope Street, # 127, Fountain Valley, CA, 92708, US

(21) Appl. No.: 09/916,627

(22) Filed: Jul. 27, 2001

(51) Int. Cl. H01L 21/76

(52) U.S. Cl. 438/424; 438/431

(57) ABSTRACT

A method is provided for forming a shallow trench isolation in a semiconductor structure is described as the followings: Firstly, a semiconductor substrate is provided, an oxide layer and a silicon layer are respectively formed. Subsequentially, an etching process is performed so that the semiconductor substrate owns a plurality of columns thereon. A second oxide layer is formed by the thermal oxidation. It is noticed that the original oxide layer is combined with the following second oxide layer as the second oxide layer. Consequentially increasing a thickness of the second oxide layer. Finally, the top surface of the third oxide layer is planazed until the silicon layer is exposed so that reducing damage in the semiconductor structure.

### BACKGROUND OF THE INVENTION

1. Field of the Invention

The present invention relates to formation of a shallow trench isolation, and more specifically, by using silicon layer as an etching mask.

2. Description of the Prior Art

The conventional prior art for forming a shallow trench isolation (S.T.I.) in the semiconductor structure is illustrated as the followings:

Firstly, with referring FIG. 1A, a semiconductor substrate is provided 11. Still as FIG. 1A, a pad oxide and a silicon nitride layer 13 are respectively formed as an etching mask layer over the substrate 11. Next, a photoresist layer 50 is formed on the silicon nitride layer 13. Then, shallow trenches are formed by etching the substrate 11.

Consequentially, as FIG. 1B, the photoresist 50 is removed. Then, the second oxide layer 12A is formed over the top surface of the semiconductor substrate 11. Obviously, it is noticed that the original first oxide layer 12 is combined with the following oxide layer 12A as the second oxide layer 12A.

Sequentially, it is shown as FIG. 1C, a second oxide layer 12B is formed and the thickness of the second oxide layer 12B is consequentinally increased over the top surface of the semiconductor substrate 11, then planarization is used to achieve planar surface.

Finally, as FIG. 1D, the silicon nitride layer 13 is removed by the conventional etching, such as hot phosphatic solution. However, unfortunatelly, the recess area 14 will appear on the second oxide layer 12B. This will make some damage for the shallow trench isolation, also, it will seriuosly attack semiconductor struacture. Even though the above problem can be solved by the thermal oxide process and the chemical etching, yet the convex area on the semiconductor structure still are not reduced.

Developments in the shallow trench isolation (S.T.I.) is still quite modest and concerned in the semiconductor fabrication. Therefore, the renewed interest in the S.T.I. is driven by the requirement to handle large numbers of integrated circuit (I.C.) manufacturers.

### SUMMARY OF THE INVENTION

In accordance with the present invention, a method is provided for forming a shallow trench isolation that substantially increases the protofile of the shallow trench isolation.

It is object for the present invention that the whole process time can be easily reduced.

It is another object for the present invention that the process cost can be exactly decreased.

It is the other object for the present invention that the damage in the semiconductor substrate will be not happened.

In the feature of the preferred embodiment, the method for forming a shallow trench isolation in a semiconductor structure is described as the followings:

Firstly, a semiconductor substrate such as silicon wafer is provided, an oxide layer and a silicon layer are respectively formed on the substrate, a photoresist is pattern on the silicon layer to define trench region. Subsequentially, an etching process is performed to etch the silicon layer, the oxide layer into the substrate. The semiconductor substrate owns a plurality of columns thereon.

After the photoresist is removed, sequentially, a second oxide layer is formed by the thermal oxidation over the top surface of the semiconductor substrate and the plurality of columns. It is noticed that the original oxide layer is combined with the following second oxide layer as the second oxide layer.

Consequentially increasing a thickness of the second oxide layer becoming as a third oxide layer is carried out until the thickness of the third oxide layer is over the thickness of the plurality of columns.

Finally, the top surface of the third oxide layer is planazed until the silicon layer is exposed so that reducing damage in the semiconductor structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A and 1D are illustrative of various components in the cross-section of the prior art; and

FIGS. 2A and 2D are illustrative of various components in the cross-section with the embodiment of the present invention.

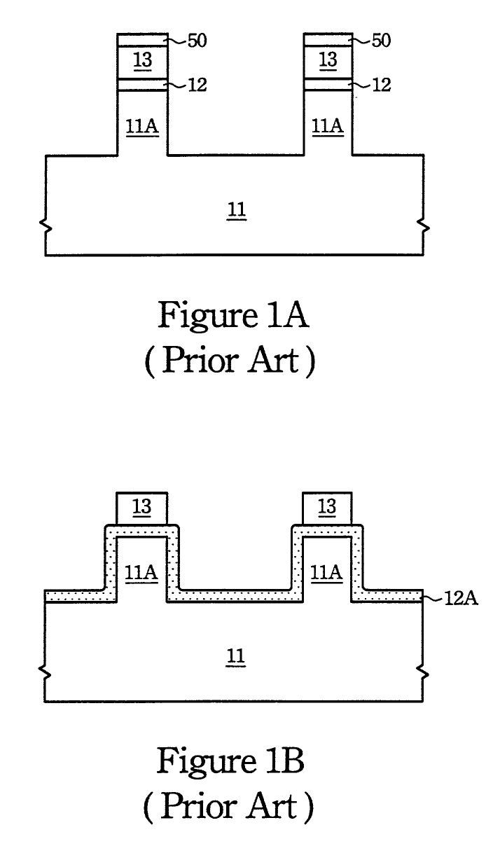

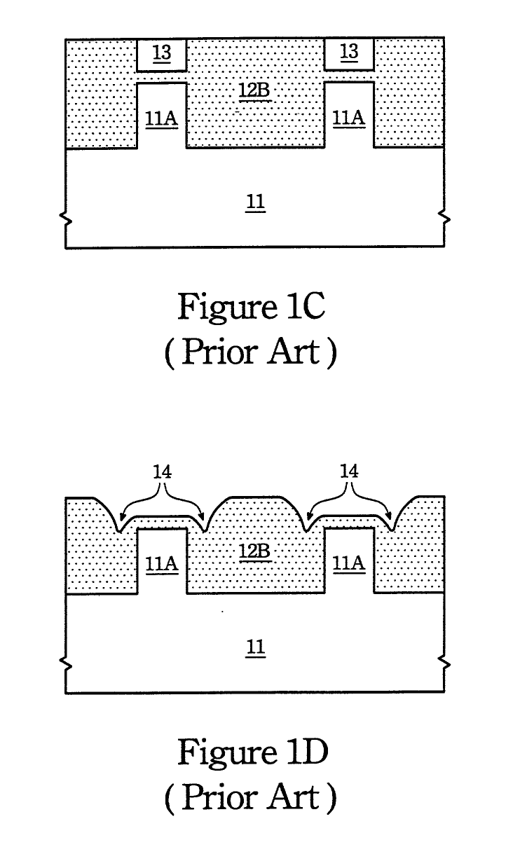

### DESCRIPTION OF THE PREFERRED EMBODIMENT

The following is a description of the present invention. The invention will firstly be described with reference to one exemplary structure. Some variations will then be described as well as advantages of the present invention. A preferred method of fabrication will then be discussed.

Moreover, while the present invention is illustrated by a number of preferred embodiments directed to shallow trench isolation, it is not intended that these illustrations be a limitation on the scope or applicability of the present invention. Further, while the illustrative examples use silicon layer, it should be recognized that the ceramic portions might be replaced with other etching mask portions. Thus, it is not intended that the semiconductor devices of the present invention be limited to the structures illustrated. These devices are included to demonstrate the utility and application of the present invention to presently preferred embodiments.

Therefore, the spirit of the proposed invention can be explained and understood by the following embodiments with corresponding figures. Especially, there is the method for forming a shallow trench isolation in a semiconductor structure according to preferred embodiment of the present invention can be described the followings:

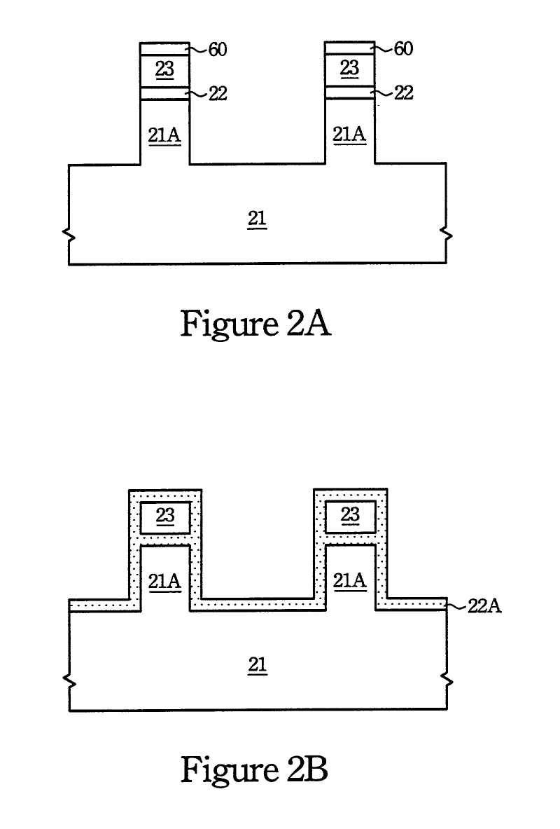

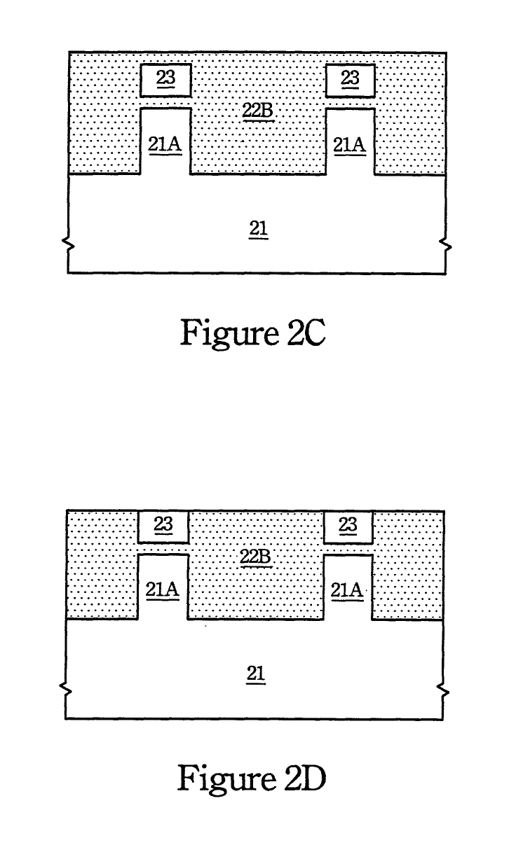

Firstly, as FIG. 2A, a semiconductor substrate 21 such as silicon wafer is provided, a first oxide layer 22 and a silicon layer 23 are respectively formed on the substrate 21 by well known technology, a photoresist 24 is pattern on the silicon layer 23 to define trench region, wherein the thickness of the first oxide layer is about 70˜150 angstroms. Subsequentially, still as FIG. 2A, an etching process is performed to etch the silicon layer 23, the oxide layer 22 and the substrate 21 to form the trenches. The semiconductor substrate 21 owns a plurality of columns 21A thereon. The silicon layer can be chosen from single crystal silicon, polysilicon and amorphous silicon. Due to the etching selectivity rate of the silicon layer is quite excellent than other semiconductor materials used in the prior art, such as silicon nitride. Also, the whole process time can be reduced because the silicon layer 22 etching and trench formation are achieved at the same working chamber. Therefore, the chamber switch is omitted.

With referring FIG. 2B, after the photoresist 60 is removed, sequentially, a second oxide layer 22A, such as silicon oxide layer is formed by the thermal oxidation over the top surface of the semiconductor substrate 21 and the plurality of columns 21A. It is noticed that the original oxide layer 22 is combined with the following second oxide layer 22A as the second oxide layer 22A. The thermal oxidation is applied to recover the etching damage.

Next, as FIG. 2C, consequentially increasing a thickness of the second oxide layer 22A becoming as a third oxide layer 22B is carried out by the conventional chemical vapor deposition until the thickness of the third oxide layer 22B is over the thickness of the plurality of columns 21A.

Finally, as FIG. 2D, the top surface of the third oxide layer 22B is planazed by the conventional chemical mechanical polish until the silicon layer 23 is exposed so that reducing damage in the semiconductor structure 21.

Therefore, according to the above statement, the advantages for the invention can be describes as the followings:

1. The whole process time can be easily reduced.

2. The process cost can be exactly decreased.

3. The damage in the semiconductor substrate will be not happened.

According to the above description, the method for forming a shallow trench isolation in a semiconductor structure can be briefly described as the followings.

Firstly, a semiconductor substrate such as silicon wafer is provided, an oxide layer and a silicon layer are respectively formed on the substrate, a photoresist is pattern on the silicon layer to define trench region. Subsequentially, an etching process is performed to etch the silicon layer, the oxide layer and the substrate to form the trenches. The semiconductor substrate owns a plurality of columns thereon.

After the photoresist is removed, sequentially, a second oxide layer is formed by the thermal oxidation over the top surface of the semiconductor substrate and the plurality of columns. It is noticed that the original oxide layer is combined with the following second oxide layer as the second oxide layer.

Consequentially increasing a thickness of the second oxide layer becoming as a third oxide layer is carried out until the thickness of the third oxide layer is over the thickness of the plurality of columns.

Finally, the top surface of the third oxide layer is planazed until the silicon layer is exposed so that reducing damage in the semiconductor structure.

Although specific embodiments have been illustrated and described, it will be obvious to those skilled in the art that various modifications may be made without departing from what is intended to be limited solely by the appended claims.

What is claimed is:

1. A method for forming a shallow trench isolation in a semiconductor structure, comprising:
providing a semiconductor substrate having a first oxide layer formed thereon;
forming a silicon layer as an etching selectivity layer over a top surface of said first oxide layer;
etching said silicon layer, said first oxide layer and said semiconductor substrate to form a plurality of trenches in said semiconductor substrate;
forming a second oxide layer over said top surface of said semiconductor substrate and sidewall of said trenches and consequentially forming a third oxide layer to refill in said trenches; and
planazing said top surface of said third oxide layer until said silicon layer is exposed so that reducing damage in the semiconductor structure.

2. The method according to claim 1, wherein the thickness of said first oxide layer is about 70˜150 angstroms.

3. The method according to claim 1, wherein said first oxide layer comprises silicon oxide layer.

4. The method according to claim 1, wherein said etching the silicon layer comprises dry etching.

5. The method according to claim 4, wherein said dry etching comprises CF₄.

6. The method according to claim 1, wherein said second oxide layer comprises thermal oxide layer.

7. The method according to claim 1, wherein said second oxide layer comprises silicon oxide layer.

8. The method according to claim 1, wherein said planazing the top surface of the third oxide layer comprises chemical mechanical polish.

9. A method for forming a shallow trench isolation in a semiconductor structure, comprising:
providing a semiconductor substrate having a first oxide layer formed thereon;
forming a silicon layer as an etching selectivity layer over a top surface of said first oxide layer;
forming a photoresist layer on said plurality of columns as an etching mask;
etching said silicon layer, said first oxide layer and said semiconductor substrate to form a plurality of trenches in said semiconductor substrate;
removing said photoresist layer;
forming a second oxide layer over said top surface of said semiconductor substrate and sidewall of said trenches;
consequentially forming a third oxide layer to refill in said trenches; and
planazing said top surface of said third oxide layer until said silicon layer is exposed so that reducing damage in the semiconductor structure.

10. The method according to claim 9, wherein the thickness of said first oxide layer is about 70˜150 angstroms.

11. The method according to claim 9, wherein said first oxide layer comprises silicon oxide layer.

12. The method according to claim 9, wherein said etching the silicon layer comprises dry etching.

13. The method according to claim 12, wherein said dry etching comprises CF₄.

14. The method according to claim 9, wherein said second oxide layer comprises thermal oxide layer.

15. The method according to claim 9, wherein said second oxide layer comprises silicon oxide layer.

16. The method according to claim 9, wherein said planazing the top surface of the third oxide layer comprises chemical mechanical polish.
